(19) United States
(12) Patent Application Publication
(10) Pub. No.: US 2026/0107410 A1
(43) Pub. Date: Apr. 16, 2026

(54) DATA STORAGE DEVICE CHASSIS FOR HEAT DISSIPATION

(71) Applicant: Seagate Technology LLC, Fremont, CA (US)

(72) Inventors: Xiong Liu, Singapore (SG); Lihong Zhang, Singapore (SG)

(21) Appl. No.: 18/915,871

(22) Filed: Oct. 15, 2024

(51) Int. Cl. H05K 7/20; H05K 7/14

(52) U.S. Cl. CPC H05K 7/20136; H05K 7/1488

(57) ABSTRACT

An apparatus includes a chassis configured to store a plurality of hard disk drives, wherein the chassis has a width between opposed sidewalls and a length. The chassis includes a bottom wall and first, second and third connectors. The bottom wall includes a plurality of columns of connectors disposed across the width. The first connector is disposed on the bottom wall in a first column. The second connector is disposed on the bottom wall in a second column that is adjacent the first column, the second column being positioned at a first width distance from the first column. The third connector is disposed on the bottom wall in a third column that is adjacent the second column, the third column being positioned at a second width distance from the second column. The first width distance is different from the second width distance.

### SUMMARY

In one embodiment, an apparatus comprises a chassis configured to store a plurality of hard disk drives, wherein the chassis has a width between opposed first and second sidewalls and a length. The chassis comprises a bottom wall, a first connector, a second connector and a third connector. The bottom wall comprises a plurality of columns of connectors disposed across the width of the chassis. The first connector is disposed on the bottom wall in a first column of the plurality of columns. The second connector is disposed on the bottom wall in a second column of the plurality of columns that is adjacent the first column, the second column being positioned at a first width distance from the first column. The third connector is disposed on the bottom wall in a third column of the plurality of columns that is adjacent the second column, the third column being positioned at a second width distance from the second column. The first width distance is different from the second width distance.

This summary and the Abstract are provided to introduce concepts in simplified form that are further described below in the Detailed Description. This summary is not intended to identify key features or essential features of the disclosed or claimed subject matter and is not intended to describe each disclosed embodiment or every implementation of the disclosed or claimed subject matter. Specifically, features disclosed herein with respect to one embodiment may be equally applicable to another. Further, this summary is not intended to be used as an aid in determining the scope of the claimed subject matter. Many other novel advantages, features, and relationships will become apparent as this description proceeds. The figures and the description that follow more particularly exemplify illustrative embodiments.

### BRIEF DESCRIPTION OF THE DRAWINGS

The disclosed subject matter will be further explained with reference to the attached figures, wherein like structure or system elements are referred to by like reference numerals throughout the several views. All descriptions are applicable to like and analogous structures throughout the several embodiments, unless otherwise specified.

FIG. 1A is a top perspective view of a base portion of an exemplary data storage device.

FIG. 1B is a bottom perspective view of an exemplary hard disk drive including a base portion containing a data storage device (as shown in FIG. 1A) and a cover attached thereto.

FIG. 2 is a perspective view of an exemplary enclosure containing a plurality of hard disk drives.

FIG. 3 is a top plan view of the enclosure of FIG. 2, wherein the hard disk drives have been removed.

FIG. 4 is an enlarged view of a bottom portion of FIG. 3, including phantom lines showing positions of hard disk drives as they would be positioned in the enclosure.

While the above-identified figures set forth one or more embodiments of the disclosed subject matter, other embodiments are also contemplated, as noted in the disclosure. In all cases, this disclosure presents the disclosed subject matter by way of representation and not limitation. It should be understood that numerous other modifications and embodiments can be devised by those skilled in the art that fall within the scope of the principles of this disclosure.

The figures may not be drawn to scale. In particular, some features may be enlarged relative to other features for clarity. Moreover, where terms such as above, below, over, under, top, bottom, side, right, left, vertical, horizontal, etc., are used, it is to be understood that they are used only for ease of understanding the description. It is contemplated that structures may be oriented otherwise.

### DETAILED DESCRIPTION

The present disclosure generally relates to data storage devices (DSD) that utilize magnetic storage media, such as hard disks. The storage capacity of hard disk drives (HDD) has steadily increased due to a boost in areal density provided by such technological advances as perpendicular recording, shingled magnetic recording (SMR), heat-assisted magnetic recording (HAMR), interleaved magnetic recording (IMR), microwave-assisted magnetic recording (MAMR), and helium filling, for example.

As hard disk drives continue to increase in capacity, there is a continuous impetus for increasing tracks per inch (TPI). One issue with increasing TPI is a corresponding increased need for cooling the HDDs, which may lead to substantial vibrational modes from fans used for cooling. This reduces a maximum areal density capability (ADC) potential of the HDD and/or reduces the density of HDDs in a chassis. It also increases the cost of the chassis and power consumption.

The address the above problems, embodiments of the disclosure provide a chassis or enclosure for HDDs that is designed such that cooling may be provided between columns of the HDDs when the HDDs are vertically mounted in the chassis (e.g., a tombstone architecture). In such embodiments, the amount of vibration experienced by the HDDs is reduced by forcing air to move in channels between the HDDs and transferring the heat out of the enclosure. A primary heat source in the HDD is electrical circuitry in its printed circuit board assembly (PCBA).

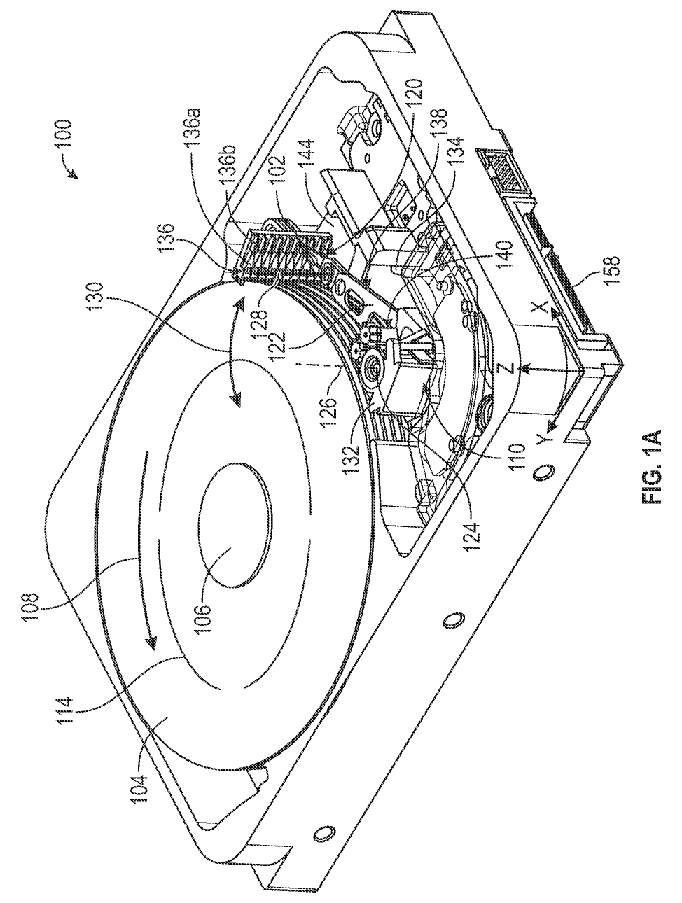

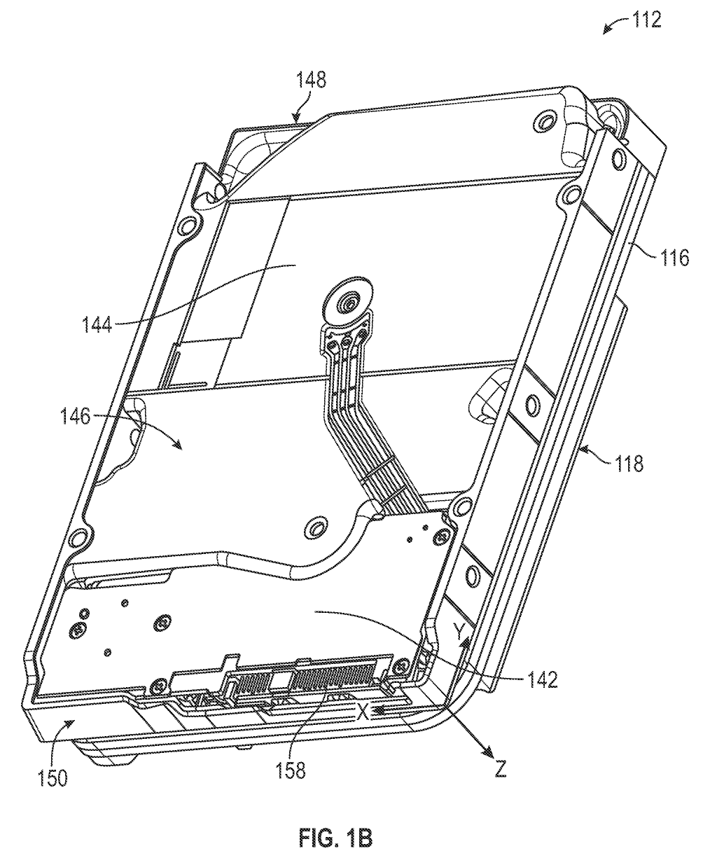

FIGS. 1A and 1B shows an illustrative embodiment of an HDD 112 including a DSD 100. The illustrated DSD 100 and HDD 112 are provided for illustration purposes only. Embodiments of the present disclosure are not limited to any particular type of DSD or HDD such as shown in FIGS. 1A and 1B. Embodiments of the present disclosure are illustratively practiced within any number of different types of DSDs and HDDs.

It should be noted that the same reference numerals are used in different figures for the same or similar elements. All descriptions of an element also apply to all other versions of that element unless otherwise stated. It should also be understood that the terminology used herein is for the purpose of describing embodiments, and the terminology is not intended to be limiting. Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “bottom,” “forward,” “reverse,” “clockwise,” “counter clockwise,” “up,” “down,” or other similar terms such as “upper,” “lower,” “aft,” “fore,” “vertical,” “horizontal,” “proximal,” “distal,” “intermediate” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

It will be understood that, when an element is referred to as being “connected,” “coupled,” or “attached” to another element, it can be directly connected, coupled or attached to the other element, or it can be indirectly connected, coupled, or attached to the other element where intervening or intermediate elements may be present. In contrast, if an element is referred to as being “directly connected,” “directly coupled” or “directly attached” to another element, there are no intervening elements present. Drawings illustrating direct connections, couplings or attachments between elements also include embodiments, in which the elements are indirectly connected, coupled or attached to each other.

FIG. 1A is a schematic illustration of a data storage device 100 in which one or more heads 102 may be positioned over or under storage media 104 to read data from and/or write data to the data storage media 104. In the embodiment shown in FIG. 1A, the data storage media 104 are rotatable data storage disks, with each disk 104 having opposing surfaces that serve as data storage surfaces. For read and write operations, a spindle 106 rotates the stack of media disks 104 as illustrated by arrow 108. An actuator mechanism 110 positions the heads 102 relative to data tracks 114 on the rotating media 104 between an inner diameter (ID) and an outer diameter (OD). Both the spindle 106 and actuator mechanism 110 are connected to and operated through drive circuitry.

In general, in order to keep read/write heads 102 from landing on disks 104 in a data storage device 100 when, for example, power is removed from the data storage device 100, and to prevent the heads 102 from colliding with outer edges of the disks 104 during load and unload operations, a head support ramp assembly 136 is provided adjacent to the OD of the disks 104. In an exemplary data storage device 100, a number of heads 102 is less than a number of disk 104 surfaces. In an exemplary embodiment, each disk 104 has a top data storage surface and a bottom data storage surface.

Each of heads 102 is coupled to the actuator mechanism 110 through a suspension assembly that includes a load beam 120 connected to an actuator arm 122 of the mechanism 110, for example through a swage connection. The actuator mechanism 110 is rotationally coupled to a frame or base 144 through a bearing 124 to rotate about axis 126. The actuator mechanism 110 moves the heads 102 in a cross-track direction as illustrated by arrow 130. Each of the heads 102 includes one or more transducer elements coupled to head circuitry through a flex circuit 134. The actuator mechanism 110, the load beam 120 and the actuator arm 122 are collectively referred to as a head stack assembly (HSA) 138. In data storage device 100 of FIG. 1A, the HSA 138 may be moved along axis 126 to different height positions under motive of an elevator 140 to interact with data storage surfaces of different disks of the stack of disks 104 carried on spindle 106.

As shown in FIG. 1A, in an exemplary embodiment, head support ramp assembly 136 supports a tab at a head end of load beam 120 when the HSA 138 is moved away from the data storage disk(s) 104. In some embodiments, head support ramp 136 includes a first ramp portion 136a adjacent to the OD of the data storage disks 104 and a second ramp portion 136b adjacent to the first ramp portion 136a. In order to move the HSA 138 from either an upper position to a lower position or from a lower position to an upper position, the HSA 138 is first rotated about axis 126, or otherwise moved in the x-y plane, until its tab is supported on the moveable portion 136b of the head-support ramp assembly 136. Then, the HSA 138 and the moveable portion 136b are moved in unison vertically (for example, in a z direction). An entire ramp 136 or a portion thereof can also be moved in the x-y plane off the disk stack, such as by retraction, flexing, or rotation, for example. Other ramp configurations can also be used, such as those described in the following commonly owned patents, which are hereby incorporated by reference: U.S. Patent 11,094,347, entitled “Split Ramp for Data Storage Devices;” and U.S. Patent 11,348,610, entitled “Movable Ramp with Arm Engaging Bracket for an Elevator Drive on a Magnetic Disk Recording Device.” Thus, the HSA 138 moves up and down to access data from multiple disk surfaces in the DSD 100.

For use of heads 102 for reading and writing data relative to disk 104, actuator 110 is activated to rotate the actuator arm 122, to thereby move the head end of HSA 138 off of the head support ramp assembly 136 and to the disk 104. To move the head end of HSA 138 onto or off a disk 104, arm 122 rotates about cylindrical bearing 124 and pivot axis 126. As shown in FIG. 1A, rotation of arm 122 about pivot axis 126 results in moving the head end of HSA 138 in an arc-shaped cross track direction 130 that is not truly on a radius of the disk 104. Accordingly, with a rotary actuator arm 122, in some positions of the head 102 on disk 104, there is some skew between the head orientation and the true track orientation of a track 114. Accordingly, in some embodiments, load beam 120 rotates relative to the actuator arm 122 at a second pivot axis 128 to reduce or eliminate any skew angle and align one or more heads 102 with a selected track 114. In an exemplary embodiment, HSA 138 is able to position head 102 relative to disk 104 in a selected cross disk position along arc 130 (about a first pivot axis 126) and with a corrected zero skew orientation of the head 102 relative to any particular track 114 due to rotation of load beam 120 relative to actuator arm 122 about a second pivot axis 128. Additional details on a suitable arm configuration with a second pivot are described in the following commonly owned patent, which is hereby incorporated by reference: U.S. Patent 11,468,909, entitled “Zero Skew with Ultrasonic Piezoelectric Swing Suspension.”

While FIG. 1A shows a particular configuration for a data storage device 100, it is to be understood that data storage devices of other forms can also be used in the enclosure of the current disclosure. More details of the illustrated data storage device 100 are provided in commonly owned US Patent Application Publication 2024/0221780 for “Single Arm Stepper Elevation System.”

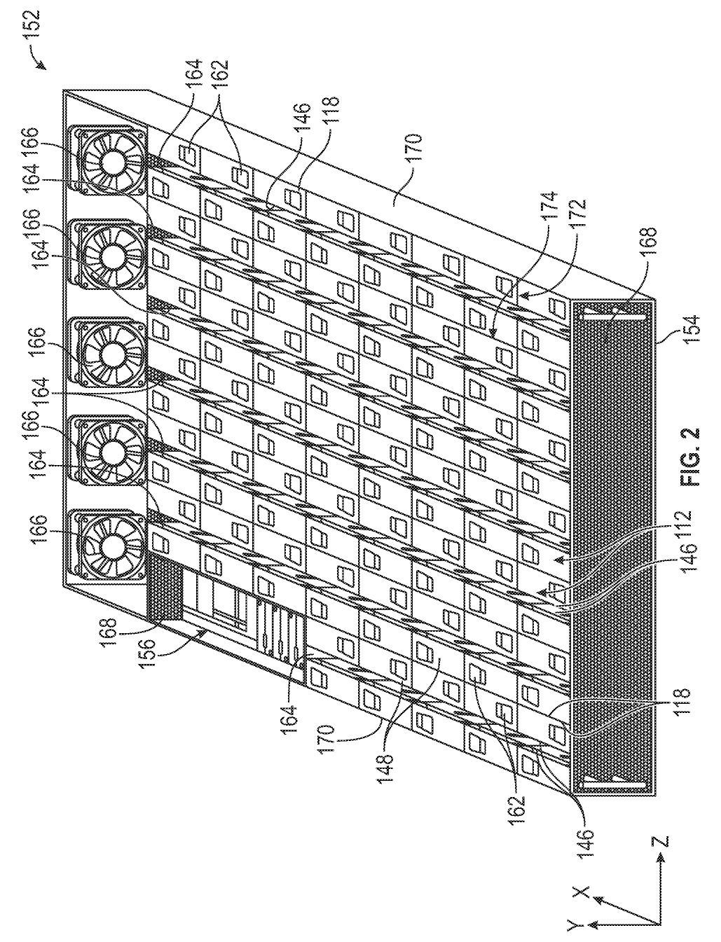

FIG. 1B shows an exemplary embodiment of a hard disk drive (HDD) 112, illustrating the exterior of the base 144 of FIG. 1, wherein the data storage device 100 is enclosed by cover 116. For simplicity we will refer to a cover side 118 and an opposed printed circuit board assembly (PCBA) side 146 that is disposed at an exterior of the base 144. When oriented vertically as shown, a top end 148 has latch 162 (visible in FIG. 2) opposite bottom end 150. It is to be understood that these descriptions are for ease of understanding the disclosure and are not limiting. The structures in other implementations can be oriented other than as illustrated and described.

In an exemplary embodiment of HDD 112 as illustrated, PCBA 142 is located at a bottom of PCBA side 146. PCBA 142 may include power supply circuitry, control circuitry to which the flex circuit 134 is coupled, a System on a Chip (SoC), Dynamic Random-Access Memory (DRAM), digital signal processing chips, servo chips, power regulator chips, and other solid state elements, for example. Such elements included in the PCBA 142 are a primary heat source in the HDD 112. For example, a temperature of a SoC can be greater than 125 C. In general, a temperature of the PCBA side 146 is significantly higher than a temperature of the cover side 118.

FIG. 2 is a perspective view of a data center rack, enclosure, or chassis 152 that includes a plurality of HDDs 112 mounted using a vertical (i.e., tombstone or toast) architecture in accordance with one embodiment. While hard disk drives are described, it is to be understood that chassis 152 can additionally or alternatively hold other data devices such as solid state drives (SDD) and graphics processing units (GPU), for example. Chassis 152 is configured to house a plurality of hard disk drives 112, wherein each of the HDDs 112 is essentially identical and interchangeable in an exemplary embodiment. The tombstone architecture involves vertically mounting the HDDs 112 on a backplane 154 (bottom surface as illustrated) of the chassis 152. The backplane 154 is a PCBA within the chassis 152 and routes power and electrical signals back and forth between HDDs 112 and an interface (such as Central Processing Unit (CPU) or controller 156, for example) to other data center devices. In some embodiments, the backplane 154 also serves as a physical support for the HDDs 112.

As illustrated, each of the HDDs 112 has a latch 162 positioned on one side of the top end 148 of the HDD 112. The plurality of HDDs 112 is arranged in an array having 14 HDDs across a width of the chassis 152 in each of 5 rows, and 12 HDDs across a width of the chassis 152 in an additional 3 rows that are positioned next to the CPU 156. Thus, in the illustrated embodiment, the array of HDDs 112 includes 14 columns of HDDs in the area without the CPU 156 and 12 columns of HDDs 112 in the area of the chassis 152 adjacent the CPU 156. The HDDs 112 are arranged so that an air flow channel 164 is located at the PCBA side 146 of each HDD 112. In interior double columns 174 of the array of HDDs 112, the cover side 118 of one column of HDDs 112 faces a cover side 118 of an adjacent column of HDDs 112. Because the cover side 118 of an HDD 112 does not heat up as much as the PCBA side 146 thereof, the cover sides 118 of adjacent HDDs 112 can be in contact with each other or have only a nominal space therebetween. Arranging the array of HDDs 112 in this manner allows more space in the enclosure to be dedicated to the airflow channels 164 for maximizing cooling fluid flow past the PCBA sides 146 of each of the HDDs 112 for an enclosure 152 of a specified size. In an exemplary embodiment of chassis 152, the movement of cooling fluid through channels 164 is facilitated by fans 166, which are configured to draw air or another cooling fluid through permeable walls 168.

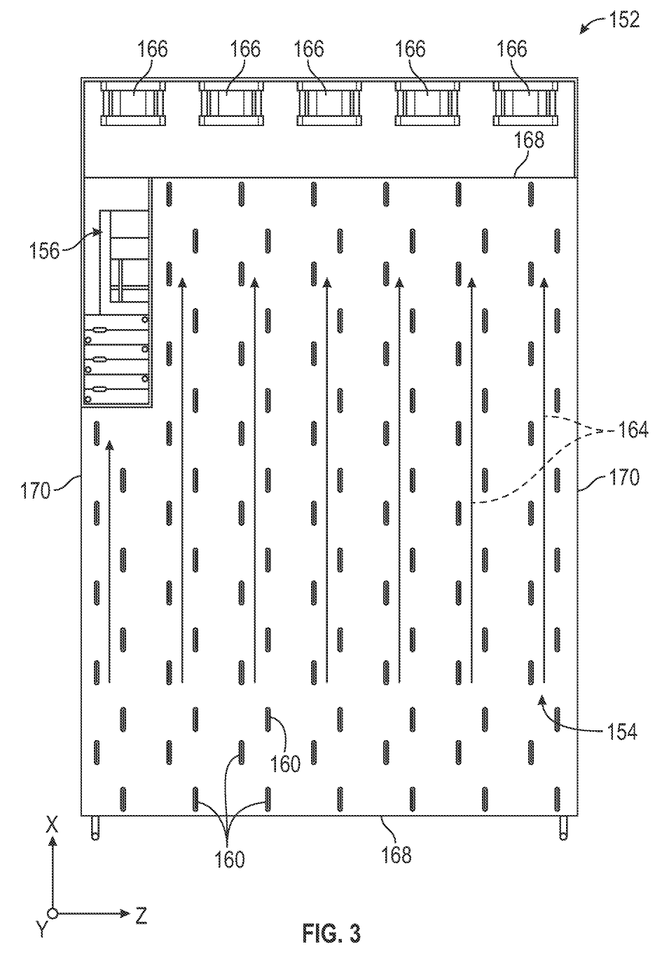

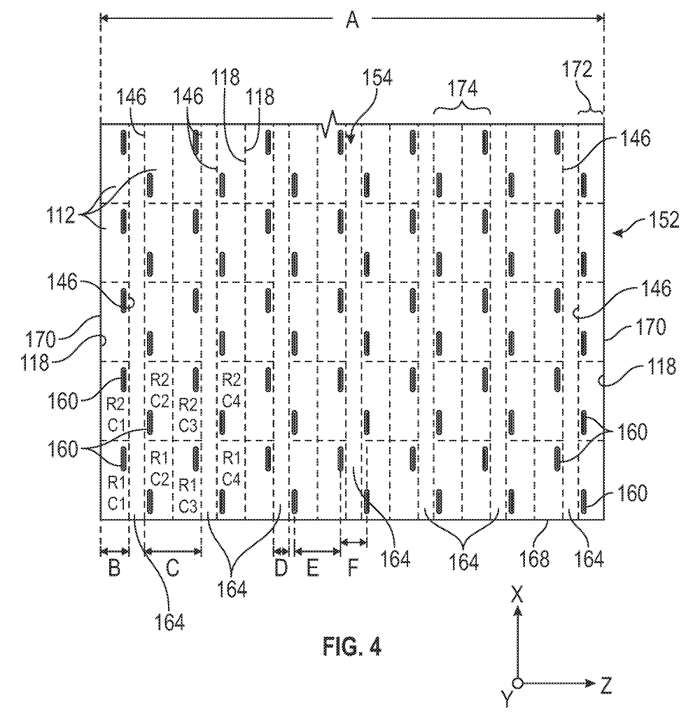

As shown in FIG. 1B, in an exemplary embodiment of HDD 112, a male connector 158 (e.g., a SAS (serial attached SCSI (small computer system interface)) connector, a SATA (serial advanced technology attachment) connector, a NVMe (nonvolatile memory express) connector etc.) on PCBA side 146 electrically couples circuitry on the PCBA 142 to circuitry on the chassis backplane 154 via attachment to corresponding female connectors 160 of backplane 154, shown in FIGS. 3 and 4.

FIG. 3 is a top plan view of an empty chassis 152 with the HDDS 112 removed therefrom. FIG. 4 is an enlarged view of a bottom portion of FIG. 3, with HDDs 112 outlined in phantom to show the relation between the positions of the HDDs and the corresponding connector 160 of enclosure chassis 152. Referring to the HDD 112 illustrated in FIG. 1B, the male connector 158 is positioned on a side of the edge between the PCBA side 146 and the bottom end 150. Referring to FIG. 4, in enclosure chassis 152 that is configured to connect to a plurality of HDDs 112, PCBA sides 146 of the HDDs 112 face airflow channels 164, and cover sides 118 of the HDDs 112 either face the cover side 118 of an adjacent HDD 112 or face a side wall 170 of the chassis 152. Thus, the corresponding female connectors 160 of back plane 154 are positioned in an exemplary embodiment as illustrated.

Descriptions will now explain relative positions of structures in an exemplary chassis 152. However, it is to be understood that enclosures can be provided in different sizes and configured to hold a different number of HDDs 112 than illustrated. In an exemplary chassis 152, a width dimension of the enclosure, herein designated as (A) is about 441 millimeters. In the coordinate system of the illustrations, the z direction is considered to be consistent with the vertical motion directions of elevator 140 of the DSD 100. When the HDDs 112, each including DSD 100, are positioned on chassis 152 with the vertical architecture illustrated in FIG. 2, the z direction corresponds to a width across the enclosure as designated in FIG. 4. A perpendicular x direction is designated along a length of the enclosure and also along lengths of the top end 148 and bottom end 150 of each HDD 112. In an exemplary embodiment, a width in the z direction of a single HDD 112 is about 26.1 millimeters, designated as dimension B. Thus, a width of 2 HDDs 112 positioned cover side to cover side in a double column 174, depending on a gap (if any) disposed between the adjacent cover sides 118, can be about 52.2 millimeter (dimension C). With 14 HDDs across each row R width-wise of the enclosure, that leaves a width designated as D of each airflow channel 164 at about 9 to 11 millimeters, depending on any gaps between facing cover sides 118 of double columns 174 of HDDs 112. Dimension E designates the distance between the center of a connector 160 and the center of a connector 160 of an adjacent HDD of a double column 174. The dimension F designates a distance between a connector 160 and that of the closest connector 160 in direction z across an airflow channel 164.

In an exemplary embodiment, at each side wall 170, a single column 172 of HDDs 112 is provided, oriented so that their cover sides 118 are positioned against or proximate side wall 170, while their PCBA sides 146 face the air flow channel 164. As shown in FIG. 2, in this orientation, latches 162 of any column C of HDDs 112 are consistently positioned toward either the front mesh wall 168 or toward the fans 166, depending on the latch configuration of a particular HDD 112 and the position of the column. Interior of the single columns 172, an exemplary embodiment of chassis 152 is configured to allow attachments of a plurality of double columns 174 of HDDs 112. An exemplary double column 174 has the cover side 118 of one of the columns of HDDs facing the cover side 118 of the other column of the double column 174, so that PCBA sides 146 of all the HDDs 112 of a double column 174 face outward to be exposed to an air flow channel 164.

Referring to FIGS. 2 and 4, in an exemplary embodiment, each of the HDDs 112 has a connector 158 that is configured for attachment to connector 160, wherein the male connector 158 is positioned on a bottom end 150 of the HDD on a same side (in direction X) of the HDD as a latch 162 is positioned on its top end 148. Moreover, the connector 158, as shown in FIG. 1B, is positioned on a PCBA side 146 of the HDD 112. Accordingly, corresponding female connectors 160 on backplane 154 of adjacent columns are staggered in the x direction. For example, referring to the lower left portion of FIG. 4, eight of the female connectors 160 are designated with row and column numbers for either row 1 (R1), row 2 (R2), column 1 (C1), column 2 (C2), column 3 (C3), or column 4 (C4). In an exemplary embodiment, for a single row, such as R1, the connectors 160 for adjacent columns are staggered in the x direction. For example, the connector 160 R1C1 is relatively higher in direction x, the connector 164 R1C2 is relatively lower, and the connector 164 R1C3 is in the same x position as that for R1C1. In each column, all of the connectors 160 have a common z axis position on backplane 154. In an exemplary embodiment, a z direction distance between connectors 160 of adjacent HDDs 112 of a double column 174 (dimension E) is greater than a distance in the z direction between the closest connectors in the z direction across an air flow channel 164 (dimension F).

The disclosed structures of chassis 152, which is configured to hold a plurality of HDDs 112, facilitate wide airflow channels 164 on the PCBA sides 146 of the HDDs 112 while efficiently packing a high number of HDDs 112 into a compact chassis 152. The exact numbers of rows and columns of HDDs 112 is not critical, as it is widely recognized that air flow channels can be wider when fewer HDDs are provided in an enclosure. Wider air flow channels 164 facilitate enhanced heat dissipation from the relatively hot PCBA sides 146 of HDDs 112; however, providing for very large heat dissipation channels can negatively affect the HDD loading capacity of a chassis 152. The disclosed chassis 152 strikes a balance between these two factors. The structure of the disclosed chassis 152 maximizes air flow at the hot PCBA sides 146 because connectors 160 are arranged so that connected HDDs 112 of adjacent columns have their cover sides 118 in contact or proximity with each other (or adjacent a side wall 170) while PCBA sides 146 of each HDD 112 are exposed to a common air flow channel 164 that is shared between the columns of HDDs 112.

Exemplary, non-limiting embodiments of a data storage device are described. In one embodiment, an apparatus comprises a chassis 152 configured to store a plurality of hard disk drives 112, wherein the chassis 152 has a width (dimension A in direction z) between opposed first and second sidewalls 170 and a length (in direction x). The chassis 152 comprises a bottom wall 154, a first connector 160, a second connector 160 and a third connector 160. The bottom wall 154 comprises a plurality of columns C of connectors 160 disposed across the width of the chassis 152. The first connector 160 is disposed on the bottom wall 154 in a first column C1 of the plurality of columns. The second connector 160 is disposed on the bottom wall 154 in a second column C2 of the plurality of columns that is adjacent the first column C1, the second column C1 being positioned at a first width distance (such as dimension F) from the first column C1. The third connector 160 is disposed on the bottom wall 154 in a third column C3 of the plurality of columns that is adjacent the second column C2, the third column C3 being positioned at a second width distance (such as dimension E) from the second column C2. The first width distance F is different from the second width distance E.

In an exemplary embodiment, the first width distance F is less than the second width distance E. However, in another case in which the first column is C2, the second column is C3, and the third column is C4, then the first width distance E is greater than the second width distance F.

In an exemplary embodiment, the first connector (such as 160 R1C1) and the second connector (such as 160 R1C2) are offset along the length (in direction x) of the chassis 152. In an exemplary embodiment, the second connector (such as 160 R1C2) and the third connector (such as 160 R1C3) are offset along the length (in direction x) of the chassis 152. In an exemplary embodiment, the first connector (such as 160 R1C1) and the third connector (such as 160 R1C3) are aligned at a same length position (in direction x) of the chassis 152.

In an exemplary embodiment, the apparatus comprises first, second and third hard disk drives 112 of the plurality of hard disk drives, wherein the first hard disk drive 112 is attached to the first connector (such as 160 R1C1), the second hard disk drive 112 is attached to the second connector (such as 160 R1C2) and the third hard disk drive 112 is attached to the third connector (such as 160 R1C3). In an exemplary embodiment, each of the first, second and third hard disk drives 112 comprises a printed circuit board assembly (PCBA) side 146 and an opposed cover side 118.

In an exemplary embodiment, the cover side 118 of the second hard disk drive 112 faces the cover side 118 of the third hard disk drive 112. In an exemplary embodiment, the cover side 118 of the second hard disk drive 112 contacts the cover side 118 of the third hard disk drive 112. In an exemplary embodiment, the PCBA side 146 of the first hard disk drive 112 faces the PCBA side 146 of the second hard disk drive 112. In an exemplary embodiment, an airflow channel 164 is disposed between the PCBA side 146 of the first hard disk drive 112 and the PCBA side 146 of the second hard disk drive 112. In an exemplary embodiment, a fan 166 is disposed proximate an end of the air flow channel 164

In an exemplary embodiment, a first width distance (dimension D) is defined between the PCBA side 146 of the first hard disk drive 112 and the PCBA side 146 of the second hard disk drive 112. A second width distance is defined between the cover side 118 of the second hard disk drive 112 and the cover side 118 of the third hard disk drive 112. The first width distance is greater than the second width distance. In an exemplary embodiment, the cover side 118 of the first hard disk drive 112 is positioned against the first sidewall 170 of the chassis 152.

The illustrations of the embodiments described herein are intended to provide a general understanding of the structure of the various embodiments. The illustrations are not intended to serve as a complete description of all of the elements and features of apparatus and systems that utilize the structures or methods described herein. Features described with respect to any embodiment also apply to any other embodiment. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be reduced. Accordingly, the disclosure and the figures are to be regarded as illustrative rather than restrictive.

One or more embodiments of the disclosure may be referred to herein, individually and/or collectively, by the term “invention” merely for convenience and without intending to limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description. All patent documents mentioned in the description are incorporated by reference.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments employ more features than are expressly recited in each claim. Rather, as the following claims reflect, inventive subject matter may be directed to less than all of the features of any of the disclosed embodiments.

The above-disclosed subject matter is to be considered illustrative, and not restrictive, and the appended claims are intended to cover all such modifications, enhancements, and other embodiments, which fall within the true spirit and scope of the present disclosure. For example, features described with respect to one embodiment may be incorporated into other embodiments. Thus, to the maximum extent allowed by law, the scope of the present disclosure is to be determined by the broadest permissible interpretation of the following claims and their equivalents, and shall not be restricted or limited by the foregoing detailed description.

1. An apparatus comprising:
a chassis configured to store a plurality of hard disk drives, wherein the chassis has a width between opposed first and second sidewalls and a length, and wherein the chassis comprises:
a bottom wall comprising a plurality of columns of connectors disposed across the width of the chassis;
a first connector disposed on the bottom wall in a first column of the plurality of columns;
a second connector disposed on the bottom wall in a second column of the plurality of columns that is adjacent the first column, the second column being positioned at a first width distance from the first column; and
a third connector disposed on the bottom wall in a third column of the plurality of columns that is adjacent the second column, the third column being positioned at a second width distance from the second column;
wherein the first width distance is different from the second width distance.

2. The apparatus of claim 1, wherein the first width distance is less than the second width distance.

3. The apparatus of claim 1, wherein the first width distance is greater than the second width distance.

4. The apparatus of claim 1, wherein the first connector and the second connector are offset along the length of the chassis.

5. The apparatus of claim 4, wherein the second connector and the third connector are offset along the length of the chassis.

6. The apparatus of claim 1, wherein the first connector and the third connector are aligned at a same length position of the chassis.

7. The apparatus of claim 1 comprising first, second and third hard disk drives of the plurality of hard disk drives, wherein:
the first hard disk drive is attached to the first connector;
the second hard disk drive is attached to the second connector; and
the third hard disk drive is attached to the third connector.

8. The apparatus of claim 7, wherein each of the first, second and third hard disk drives comprises:
a printed circuit board assembly (PCBA) side; and
an opposed cover side.

9. The apparatus of claim 8, wherein the cover side of the second hard disk drive faces the cover side of the third hard disk drive.

10. The apparatus of claim 9, wherein the cover side of the second hard disk drive contacts the cover side of the third hard disk drive.

11. The apparatus of claim 8, wherein the PCBA side of the first hard disk drive faces the PCBA side of the second hard disk drive.

12. The apparatus of claim 11, wherein an air flow channel is disposed between the PCBA side of the first hard disk drive and the PCBA side of the second hard disk drive.

13. The apparatus of claim 12 comprising a fan disposed proximate an end of the air flow channel.

14. The apparatus of claim 11, wherein:
a first width distance is defined between the PCBA side of the first hard disk drive and the PCBA side of the second hard disk drive;
a second width distance is defined between the cover side of the second hard disk drive and the cover side of the third hard disk drive; and
the first width distance is greater than the second width distance.

15. The apparatus of claim 8, wherein the cover side of the first hard disk drive is positioned against the first sidewall of the chassis.
